(19) United States
(12) Patent Application Publication
(10) Pub. No.: US 2026/0082915 A1
(43) Pub. Date: Mar. 19, 2026

(54) COOLER

(71) Applicant: FUJI ELECTRIC CO., LTD., Kawasaki-shi (JP)

(72) Inventors: Akira KAMIYA, Tokyo (JP); Takumi SATO, Tokyo (JP); Takashi SHIRAKI, Tokyo (JP); Daiki SANO, Matsumoto-city (JP)

(73) Assignee: FUJI ELECTRIC CO., LTD., Kawasaki-shi (JP)

(21) Appl. No.: 19/311,670

(22) Filed: Aug. 27, 2025

(30) Foreign Application Priority Data
Sep. 13, 2024 (JP) 2024-159057

(51) Int. Cl. H01L 23/473

(52) U.S. Cl. CPC H10W 40/47

(57) ABSTRACT

A cooler includes: an inlet for a refrigerant; an outlet for the refrigerant; a first member with a first surface that absorbs heat from a cooled body and a second surface opposite to the first surface; a second member with a third surface facing the second surface; and columnar protrusions extending from the third surface toward the second surface. The protrusions are grouped into two or more protrusion rows that are arranged at intervals along a first direction of flow of the refrigerant. A distance between a first protrusion row closest to the inlet and a second protrusion row next closest to the inlet after the first protrusion row is greater than a distance between a third protrusion row closest to the outlet and a fourth protrusion row next closest to the outlet after the third protrusion row.

### CROSS REFERENCE TO RELATED APPLICATION

This Application claims priority from Japanese Patent Application No. 2024-159057, filed September 13, 2024, the entire content of which is incorporated herein by reference.

### BACKGROUND

### TECHNICAL FIELD

This disclosure relates to coolers.

### Description of Related Art

A known semiconductor device, such as a power converter, converts DC power into AC power. Such a semiconductor device has a cooler that dissipates heat from a heat generating element.

A cooler, described in WO 2014/069174 A1, includes a substrate for heat dissipation joined to an insulating substrate with a semiconductor element, fins opposing the insulating substrate, and a box-shaped cooling case for the fins. The cooling case has an inlet and an outlet for a refrigerant, and the refrigerant flows into the cooling case. These fins are arranged at a predetermined pitch at specific intervals. The arrangement of the fins increases the heat dissipation area, resulting in efficient heat exchange.

### SUMMARY

A flowing refrigerant absorbs heat from a body being cooled by the refrigerant. Consequently, the temperature of the refrigerant is higher near the outlet than at the inlet. If protrusions designed to increase a flow velocity of the refrigerant are evenly distributed throughout the region, the flow remains uniform. However, since the temperature of the refrigerant rises on the downstream, the cooling performance of the substrate for heat dissipation becomes uneven. As a result, the temperature of the cooled body is generally higher on the downstream.

In order to solve the aforementioned problems, a cooler, according to this disclosure, includes a case including: an inlet for a refrigerant; an outlet for the refrigerant; a first member with a first surface that absorbs heat from a cooled body and a second surface opposite to the first surface; a second member with a third surface facing the second surface; and a plurality of columnar protrusions that extends from the third surface toward the second surface. The plurality of protrusions is grouped into two or more protrusion rows that are arranged at intervals along a first direction of flow of the refrigerant. The two or more protrusion rows includes: a first protrusion row closest to the inlet; a second protrusion row next closest to the inlet after the first protrusion row; a third protrusion row closest to the outlet; and a fourth protrusion row next closest to the outlet after the third protrusion row. A distance between the first protrusion row and the second protrusion row is greater than a distance between the third protrusion row and the fourth protrusion row.

### BRIEF DESCRIPTION OF DRAWINGS

FIG. 1 is a perspective view of a cooler according to a first embodiment.

FIG. 2 is a perspective view of a second member included in the cooler illustrated in FIG. 1.

FIG. 3 includes a top view, a front view, side views, and a cross-sectional view of the second member in FIG. 2.

FIG. 4 is a cross-sectional view of protrusions illustrated in FIG. 2.

FIG. 5 is a plan view of protrusions illustrated in FIG. 2.

FIG. 6 illustrates thermal resistances in both this embodiment and a comparative example.

FIG. 7 illustrates protrusions and baffles according to a second embodiment.

FIG. 8 is a cross-sectional view of the protrusions and the baffles illustrated in FIG. 7.

FIG. 9 illustrates a flow of refrigerant in the comparative example.

FIG. 10 illustrates a flow of refrigerant in the second embodiment.

FIG. 11 illustrates a flow velocity of the refrigerant in the comparative example.

FIG. 12 illustrates a flow velocity of the refrigerant in the second embodiment.

FIG. 13 illustrates protrusions and baffles shown in FIG. 7.

FIG. 14 illustrates protrusions and baffles according to a first modification.

FIG. 15 is a plan view illustrating baffles according to a second modification.

FIG. 16 is a plan view illustrating baffles according to a third modification.

FIG. 17 is a plan view illustrating baffles according to a fourth modification.

FIG. 18 is a plan view illustrating baffles according to a fifth modification.

FIG. 19 is a cross-sectional view of a baffle according to a sixth modification.

FIG. 20 is a cross-sectional view of a baffle according to a seventh modification.

FIG. 21 is a cross-sectional view of a baffle according to an eighth modification.

### DESCRIPTION OF EMBODIMENTS

Embodiments according to this disclosure will be described below with reference to the accompanying drawings. In the drawings, dimensions and scales of parts are appropriately different from actual ones, and some of the parts are schematically illustrated for clarity. The scope of this disclosure is not limited to these forms unless otherwise specified in the following description to the effect that this disclosure is limited thereto. In this specification, the term “equal” not only means substantially equal, but also includes a difference due to a manufacturing error.

### 1. First Embodiment

### 1-1 Overview of Cooler 100

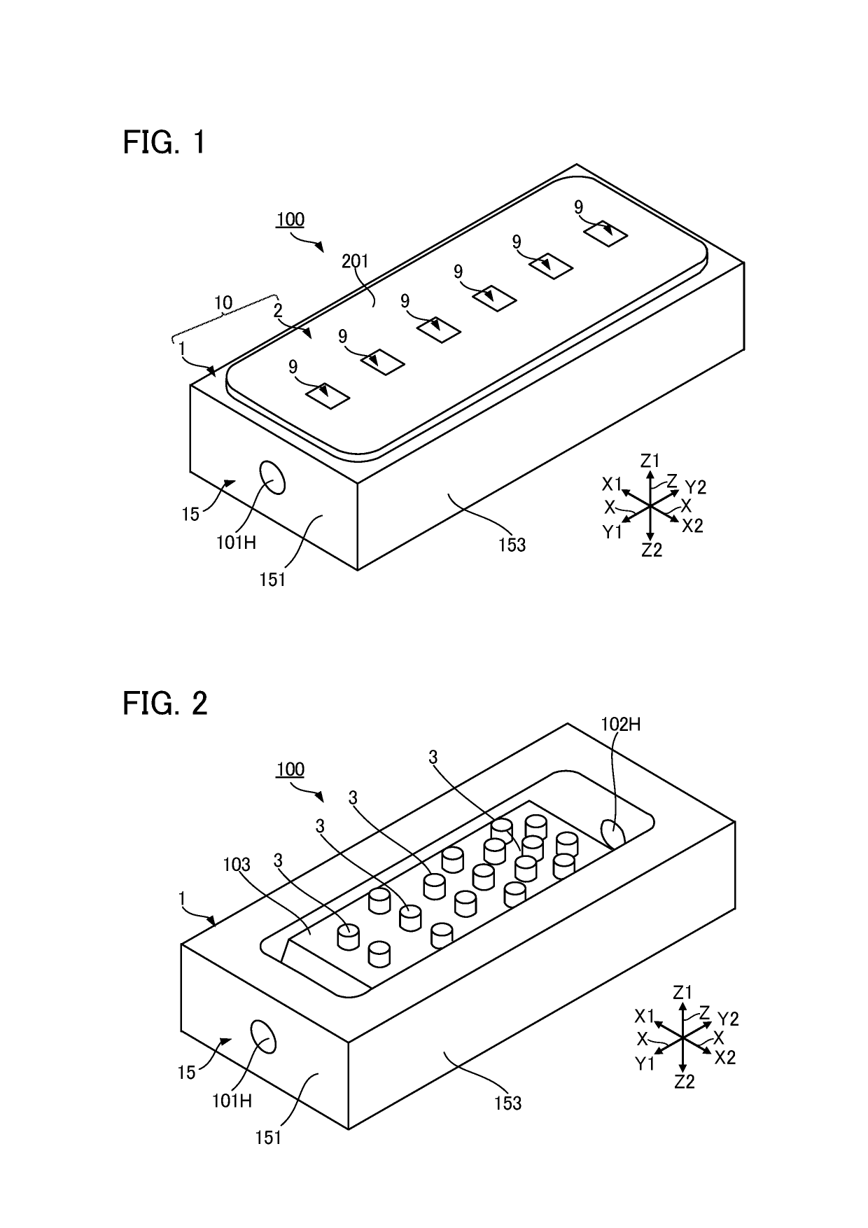

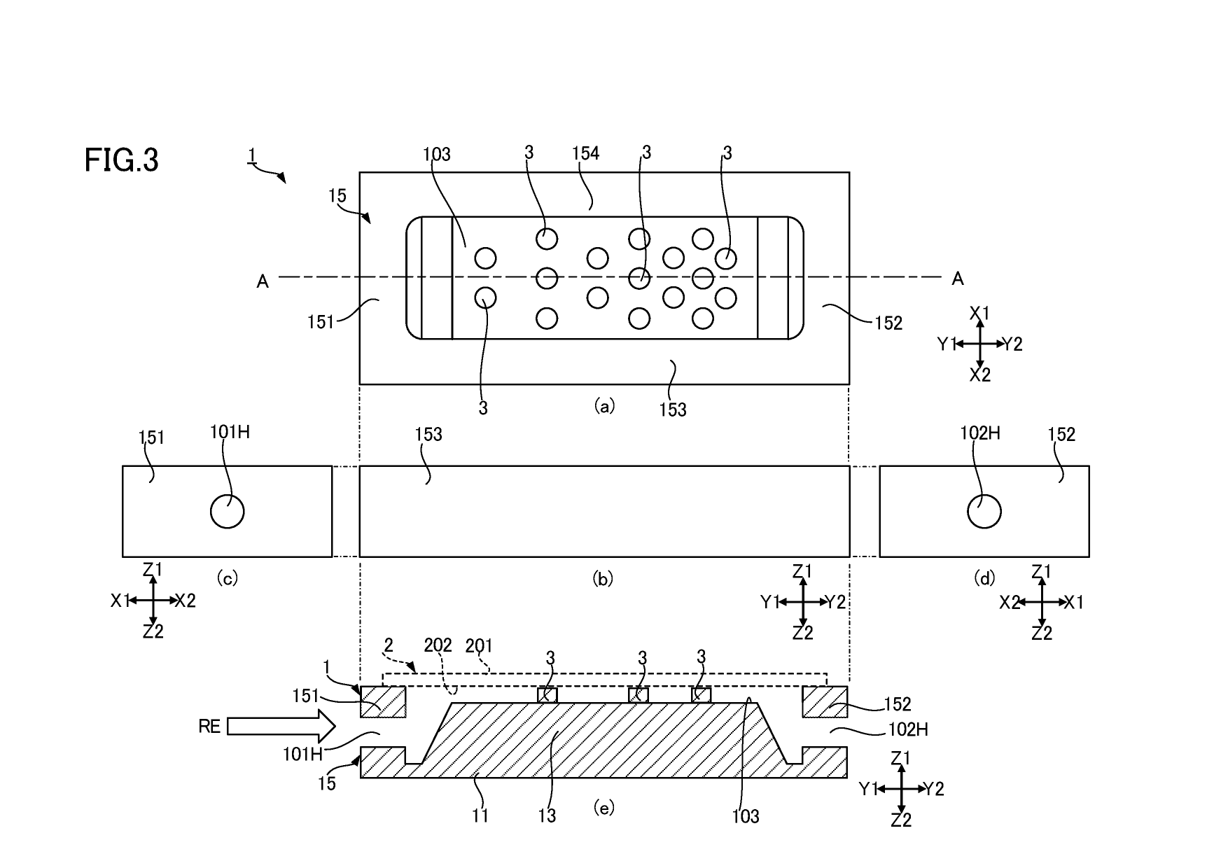

FIG. 1 is a perspective view of a cooler 100 according to a first embodiment. FIG. 2 is a perspective view of a second member 1 included in the cooler 100 illustrated in FIG. 1. FIG. 3 includes a top view (a), a front view (b), side views (c and d), and a cross-sectional view (e) of a second member 1 of FIG. 2.

The following description will be given while appropriately using an X axis, a Y axis, and a Z axis that intersect with each other. The “X1” represents the X axis in a positive direction, and the “X2” represents the X axis in a negative direction. The “Y1” represents the Y axis in a positive direction, and the “Y2” represents the Y axis in a negative direction. The “Z1” represents the Z axis in a positive direction, and the “Z2” represents the Z axis in a negative direction. A view in a direction along the Z axis is referred to as a “plan view.” The Z1 also corresponds to an upward direction, and the Z2 also corresponds to a downward direction.

The cooler 100 illustrated in FIG. 1 is used to cool power electronics products, such as inverters and rectifiers. These components may be mounted in railway vehicles, automobiles, or household electrical applications. The power electronic products may have power semiconductor elements, such as diodes, or insulated gate bipolar transistors (IGBTs). The power semiconductor elements are examples of cooled bodies 9, which are subjected to be cooled by the cooler 100. As heat generating element, the cooled bodies 9 are not limited to these power semiconductor elements. The cooled bodies 9 may be any other electric components that generate heat when driven or energized and require cooling.

As illustrated in FIGS. 1 to 3, the cooler 100 includes a case 10 and protrusions 3.

### 1-1a. Case 10

The case 10 has an internal space that serves as a flow path for a refrigerant RE. The case 10 has an inlet 101H through which the refrigerant RE enters, and an outlet 102H through which the refrigerant RE exits. The refrigerant RE flows into the flow path from the inlet 101H and is discharged from the outlet 102H. As such, the refrigerant RE flows from the inlet 101H toward the outlet 102H.

The refrigerant RE is a medium in a liquid state at room temperature, and it may consist of water (e.g., pure water), or a mixture of water and an alcohol. The alcohol may be ethanol or methanol. The type of the refrigerant RE may be a type other than these types. A surfactant is preferably added to the refrigerant RE. The surfactant may be a nonionic surfactant, or an ionic surfactant, such as an anionic surfactant and a cationic surfactant. Specific examples of the surfactant include a fluorine-based surfactant, a silicone-based surfactant, and a hydrocarbon-based surfactant. When the refrigerant is water, it is preferable to use a hydrocarbon-based surfactant having excellent solubility.

The case 10 is made of a material with excellent thermal conductivity, such as copper, aluminum, and an alloy. The case 10 includes a first member 2 and a second member 1. The second member 1 is a box with an opening oriented in the Z1 direction. The first member 2 is a lid that covers the opening. The first member 2 and the second member 1 may be made of the same material or different materials.

As illustrated in FIG. 3, the second member 1 is flat. The first member 2 has a first surface 201 and a second surface 202. As illustrated in FIG. 1, more than two cooled bodies 9 are arranged on the first surface 201 and are cooled by the cooler. The first surface 201 absorbs heat from the cooled bodies 9. The first surface 201 and each cooled body 9 may be in direct contact with each other, or another member may be interposed between the first surface 201 and each cooled body 9. The second surface 202 is opposite to the first surface 201.

The second member 1 includes a bottom 11, a side wall 15, and a base 13. The bottom 11, the side wall 15, and the base 13 are unitarily formed; however, they may be individual elements that are bonded together. The bottom 11 is flat.

The side wall 15 extends in the Z1 direction from the bottom 11. The side wall 15 has a first side wall 151, a second side wall 152, a third side wall 153, and a fourth side wall 154. The first side wall 151 and the second side wall 152 face each other, and the third side wall 153 and the fourth side wall 154 face each other. The inlet 101H is located on the first side wall 151. The outlet 102H is located on in the second side wall 152. The inlet 101H is an opening penetrating through the first side wall 151, and the outlet 102H is an opening penetrating through the second side wall 152.

The base 13 is positioned relative to the bottom 11 in the Z1 direction and is thicker than the bottom 11 along the Z axis. In one example, the base 13 is trapezoidal in cross-section. The base 13 enhances the cooling performance of the cooler 100 as compared to that without the base. The base 13 has an upper surface corresponding to a third surface 103 facing the second surface 202.

### 1-1b. Protrusions 3

As illustrated in FIGS. 2 and 3, the protrusions 3 are spaced apart and arranged within the internal space of the case 10. Each protrusion 3 is a columnar protrusion connected to the third surface 103 and extends toward the second surface 202. Each protrusion 3 does not contact the second member 1; however, each may be in contact with the second member 1. In this example, each protrusion 3 is cylindrical.

The arranged protrusions 3 increase a flow velocity of the refrigerant RE in contact with the second surface 202 of the first member 2, which enhances the cooling performance of the cooler 100.

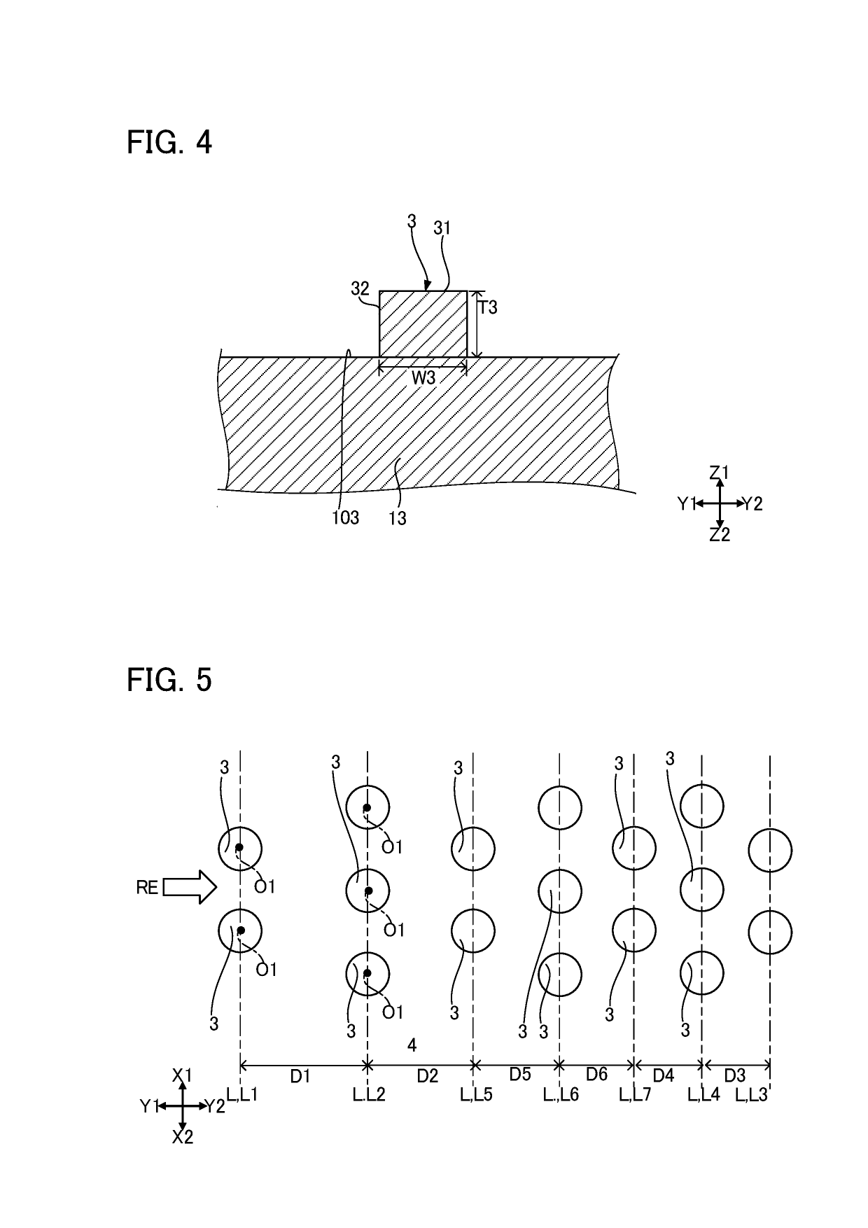

FIG. 4 is a cross-sectional view of the protrusions 3 illustrated in FIG. 2. FIG. 5 is a plan view of the protrusions 3 illustrated in FIG. 2.

As illustrated in FIG. 4, each protrusion 3 has a protruding height T3 along the X axis, and a width W3 along the Y axis. The refrigerant RE flows in the direction of the Y axis. Each protrusion 3 has a top surface 31 and a side surface 32. The top surface 31 is a portion of the protrusion 3 closest to the second surface 202. In this embodiment, the top surface 31 is parallel to the third surface 103 and is orthogonal to the Z axis. The top surface 31 is circular in plan view. The side surface 32 is cylindrical and connects the top surface 31 to the third surface 103. In this embodiment, the side surface 32 is parallel to the Z axis.

As illustrated in FIG. 5, the protrusions 3 are arranged in a staggered pattern in plan view. The protrusions 3 are grouped into two or more protrusion rows L, which are arranged at intervals along the Y2 direction. The Y2 direction corresponds to the direction of flow of the refrigerant RE. In this example, the protrusions 3 are grouped into seven protrusion rows L. Each protrusion row L is a set of protrusions 3 linearly arranged along the X axis. In this embodiment, these protrusion rows L are arranged at equal intervals.

From among these protrusion rows L, a protrusion row L closest to the inlet 101H is defined as a first protrusion row L1. A protrusion row L next closest to the inlet 101H after the first protrusion row L1 is defined as a second protrusion row L2. A protrusion row L next closest to the inlet 101H after the second protrusion row L2 is defined as a fifth protrusion row L5. A protrusion row L next closest to the inlet 101H after the fifth protrusion row L5 is defined as a sixth protrusion row L6. A protrusion row L next closest to the inlet 101H after the sixth protrusion row L6 is defined as a seventh protrusion row L7. From among these protrusion rows L, a protrusion row L closest to the outlet 102H is defined as a third protrusion row L3. A protrusion row L next closest to the outlet 102H after the third protrusion row L3 is defined as a fourth protrusion row L4.

The distances between two adjacent protrusion rows L are not uniform. Specifically, a distance D1 between the first protrusion row L1 and the second protrusion row L2 is greater than a distance D3 between the third protrusion row L3 and the fourth protrusion row L4.

The temperature of the refrigerant RE is generally greater near the outlet 102H than near the inlet 101H. By reducing the distance between protrusion rows L closer to the outlet 102H, as compared to the inlet 101H, the flow velocity of the refrigerant RE increases in vicinity of the outlet 102H. This adjustment reduces uneven cooling on the first surface 201 of the second member 1.

Furthermore, distances between two adjacent protrusion rows L gradually decrease from the inlet 101H toward the outlet 102H. Specifically, distances gradually decrease in order from distance D1: a distance D2 between the second protrusion row L2 and the fifth protrusion row L5, a distance D5 between the fifth protrusion row L5 and the sixth protrusion row L6, a distance D6 between the sixth protrusion row L6 and the seventh protrusion row L7, a distance D4 between the seventh protrusion row L7 and the fourth protrusion row L4, and finally, the distance D3. That is, the distances D1, D2, D5, D6, D4, and D3 satisfy the relationship D1 > D2 > D5 > D6 > D4 > D3.

Since the distances between two adjacent protrusion rows L gradually decrease from the inlet 101H toward the outlet 102H, the flow velocity of the refrigerant RE correspondingly increases. As a result, uneven cooling performance on the first surface 201 of the second member 1 can be effectively reduced.

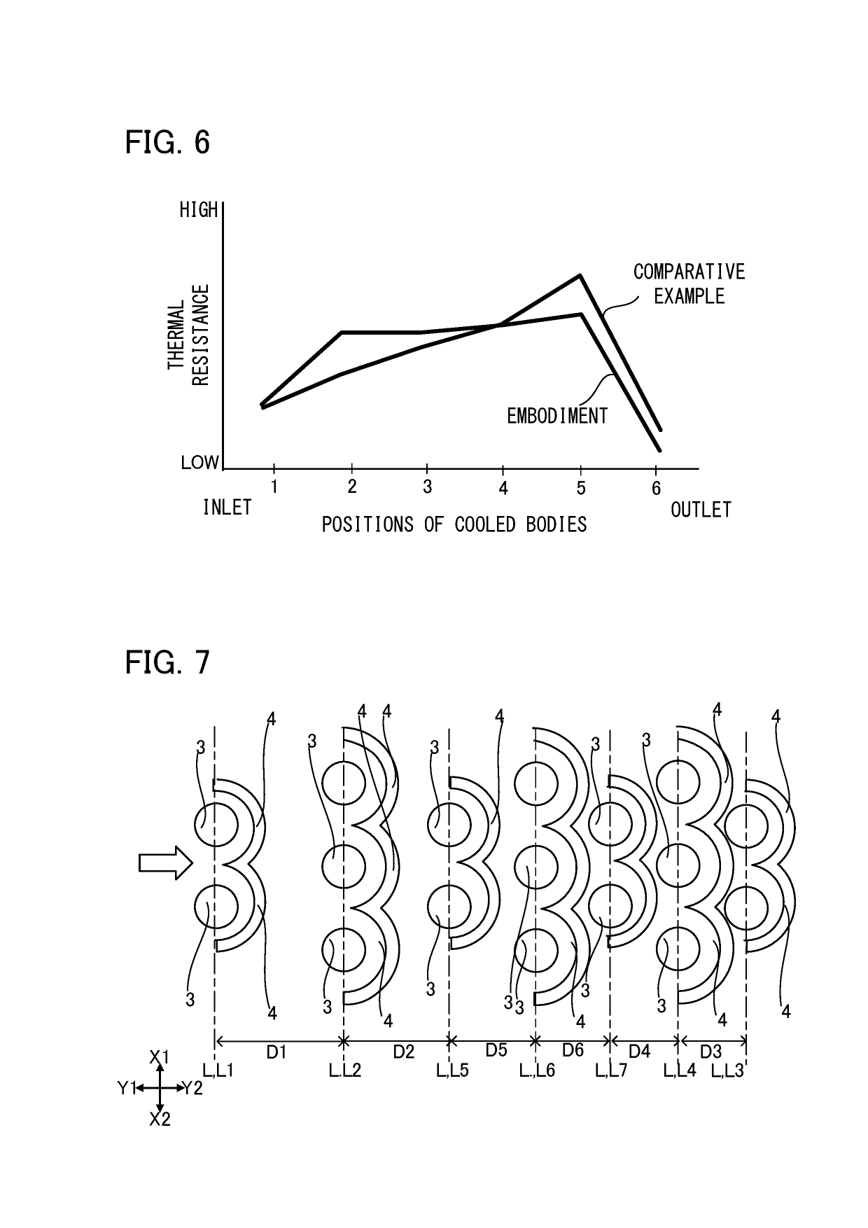

FIG. 6 illustrates thermal resistances in both this embodiment and the comparative example. In FIG. 6, the vertical axis represents thermal resistances of the cooled bodies 9, and the horizontal axis represents positions thereof. Specifically, six cooled bodies 9 are arranged on the first surface 201. A cooled body 9 closest to the inlet 101H is numbered “1,” and the remaining cooled bodies 9 are numbered “2,” “3,” “4,” “5,” and “6” sequentially toward the outlet 102H, starting from “1.” In the comparative example, these six cooled bodies 9 are arranged in a straight line at substantially equal intervals from the inlet 101H toward the outlet 102H.

As illustrated in FIG. 6, the thermal resistance of a cooled body 9 close to the outlet 102H is reduced as compared with that in the comparative example. As shown in FIG. 6, the cooler 100 of this embodiment increases a flow velocity of the refrigerant RE toward the outlet 102H by reducing a distance between protrusion rows L closer to the outlet 102H, as compared to the inlet 101H. This adjustment reduces uneven cooling on the first surface 201 of the first member 2.

As illustrated in FIG. 5, when viewed from the Y2 direction (i.e., a direction of flow of the refrigerant RE), the center of each protrusion 3 in a certain protrusion row L does not overlap with the center of each protrusion 3 located within an adjacent protrusion row L.

The arrangement of the protrusions 3 facilitates a smooth flow of the refrigerant RE over the entire internal space and effectively reduces uneven cooling on the first surface 201.

### 2. Second Embodiment

Description will now be given of a second embodiment of this disclosure. In the following exemplary embodiment, reference signs from the first embodiment will be used for elements with similar actions and functions. Detailed description of these elements will be omitted as appropriate.

FIG. 7 illustrates protrusions 3 and baffles 4 according to the second embodiment. As illustrated in FIG. 7, the cooler 100 according to the second embodiment has baffles 4.

The baffles 4 are located within the internal space of the case 10. Each baffle 4 is a columnar protrusion connected to the third surface 103 and extends toward the second surface 202. The baffles 4 are arranged for the respective protrusions 3. In this embodiment, the wall-shaped baffles 4 correspond one-to-one to the protrusions 3. The baffles 4 are spaced apart from the protrusions 3.

As described above, the baffles 4 correspond one-to-one to the protrusions 3. Each baffle 4 is disposed close to the outlet 102H of the corresponding protrusion 3. In this embodiment, each baffle 4 has an arc shape in plan view. Furthermore, baffles 4, corresponding to protrusions 3 located within the same protrusion row L, are connected to each other.

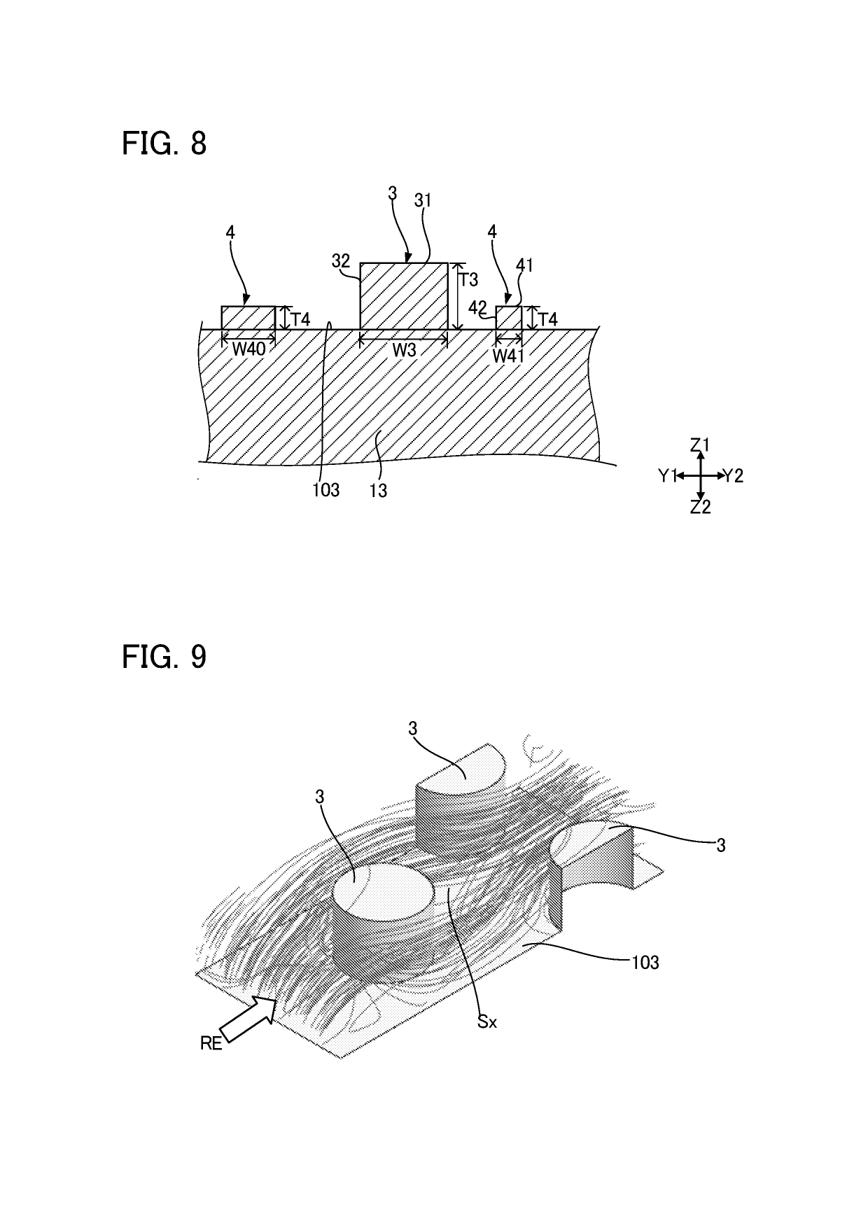

FIG. 8 is a cross-sectional view of the protrusions 3 and the baffles 4 illustrated in FIG. 7. As illustrated in FIG. 8, each protrusion 3 has a protruding height T3 along the Z axis (the direction of Z1) that is greater than a protruding height T4 of each baffle 4 along the Z axis.

Each baffle 4 has a top surface 41 and a side surface 42. The top surface 41 is a portion of the baffle 4 closest to the second surface 202. In this embodiment, the top surface 41 is parallel to the third surface 103 and is orthogonal to the Z axis. The top surface 41 is circular in plan view. The side surface 42 is cylindrical and connects the top surface 41 to the third surface 103. In this embodiment, the side surface 42 is parallel to the Z axis.

As described above, each protrusion 3 has the protruding height T3 along the Z axis (the direction of Z1) that is greater than the protruding height T4 of each baffle 4 along the Z axis. The baffle 4 is spaced apart from the corresponding protrusion 3 and is disposed on a side opposite the inlet 101H relative to this protrusion 3. Such a baffle 4 serves to prevent deceleration of flow of the refrigerant RE in the downstream region of the protrusion 3 (the region toward the outlet 102H), thereby enhancing the cooling performance of cooler 100.

The protruding height T4 of the baffle 4 is less than the protruding height T3 of the protrusion 3. If the protruding height T4 is equal to or greater than the protruding height T3, the flow rate and flow velocity of the refrigerant RE may decrease in the downstream region of the baffle 4 (the region toward the outlet 102H). However, since the protruding height T4 is less than the protruding height T3, a decrease in flow rate and the flow velocity is unlikely to occur.

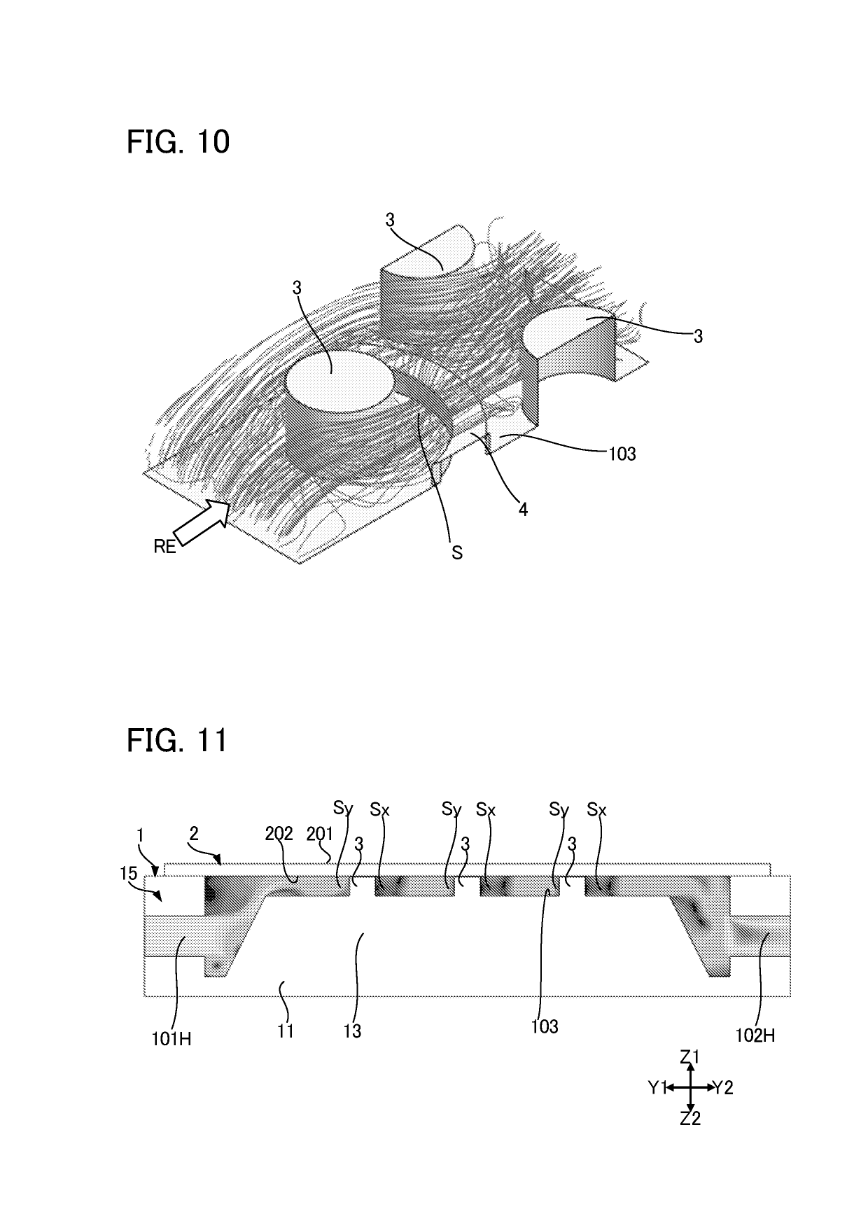

FIG. 9 illustrates a flow of refrigerant RE in the comparative example. FIG. 10 illustrates a flow of refrigerant RE in the second embodiment. In the comparative example illustrated in FIG. 9, no baffle 4 is provided. Conversely, in the second embodiment illustrated in FIG. 10, a baffle 4 is provided. Flow lines of the refrigerants RE are depicted In FIGS. 9 and 10.

In the comparative example of FIG. 9, the refrigerant RE exhibits minimal flow in a downstream region Sx of the protrusion 3 (the region toward the outlet 102H). Conversely, in the second embodiment of FIG. 10, the refrigerant RE efficiently flows also in a downstream region S of the protrusion 3 (the region toward the outlet 102H), similar to its flow in the upstream region (the region toward the inlet 101H). This is because the refrigerant RE impacts the upstream region of the baffle 4 (the region toward the inlet 101H), which causes a change in directions of flow within the region S between protrusion 3 and baffle 4. As a result, the flow rate of the refrigerant RE passing through the region S increases in the second embodiment, compared to the downstream the region Sx of the protrusion 3 (the region toward the outlet 102H).

As illustrated in FIGS. 9 and 10, each arranged baffle 4 serves to prevent a decrease in flow rate in the downstream region S of the protrusion 3 (the region toward the outlet 102H).

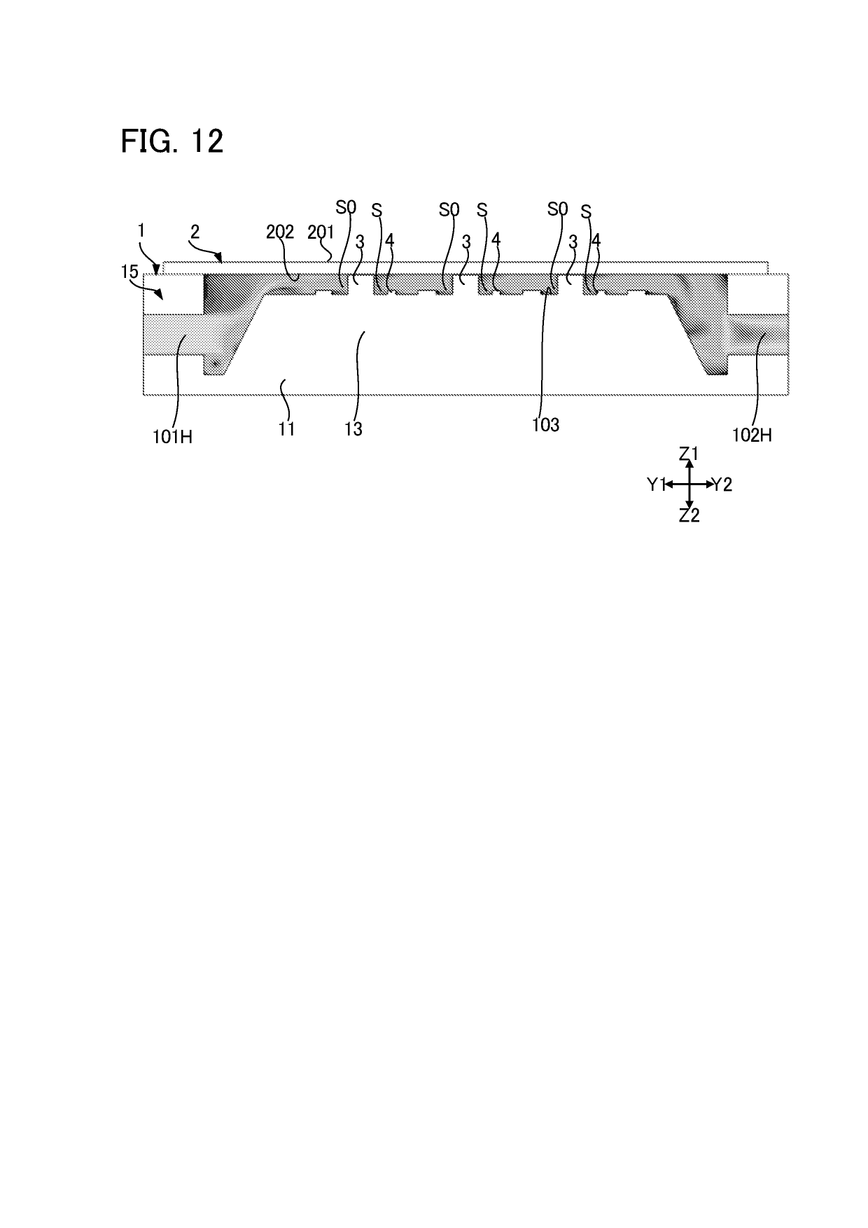

FIG. 11 illustrates the magnitude of the flow velocity of the refrigerant RE in the comparative example. FIG. 12 illustrates the magnitude of the flow velocity of the refrigerant RE in the second embodiment. In the comparative example of FIG. 11, a brightness level of the downstream region Sx of the protrusion 3 (the region toward the outlet 102H) is less than that of an upstream region Sy of the protrusion 3 (the region toward the inlet 101H). This indicates that a flow velocity of the refrigerant RE in the region Sx is less than that of the refrigerant RE in the region Sy.

In the second embodiment shown FIG. 12, the brightness level of the downstream region S of the protrusion 3 (the region toward the outlet 102H) is substantially equal to that of an upstream region S0 of the protrusion 3 (the region toward the inlet 101H). This indicates that a flow velocity of the refrigerant RE in the region S is not inferior to that of the refrigerant RE in the region S0, but is substantially equal to the flow velocity of the refrigerant RE in the region S0.

As illustrated in FIGS. 11 and 12, each arranged baffle 4 serves to prevent a decrease in flow velocity in the downstream region S of the protrusion 3 (the region toward the outlet 102H).

The protruding height T4 of the baffle 4 is less than the protruding height T3 of the protrusion 3. If the protruding height T4 is equal to or greater than the protruding height T3, the flow rate and flow velocity of the refrigerant RE may decrease in the downstream region of the baffle 4 (the region toward the outlet 102H). Conversely, if the protruding height T4 is less than the protruding height T3, the decrease in flow rate and the flow velocity rarely occurs.

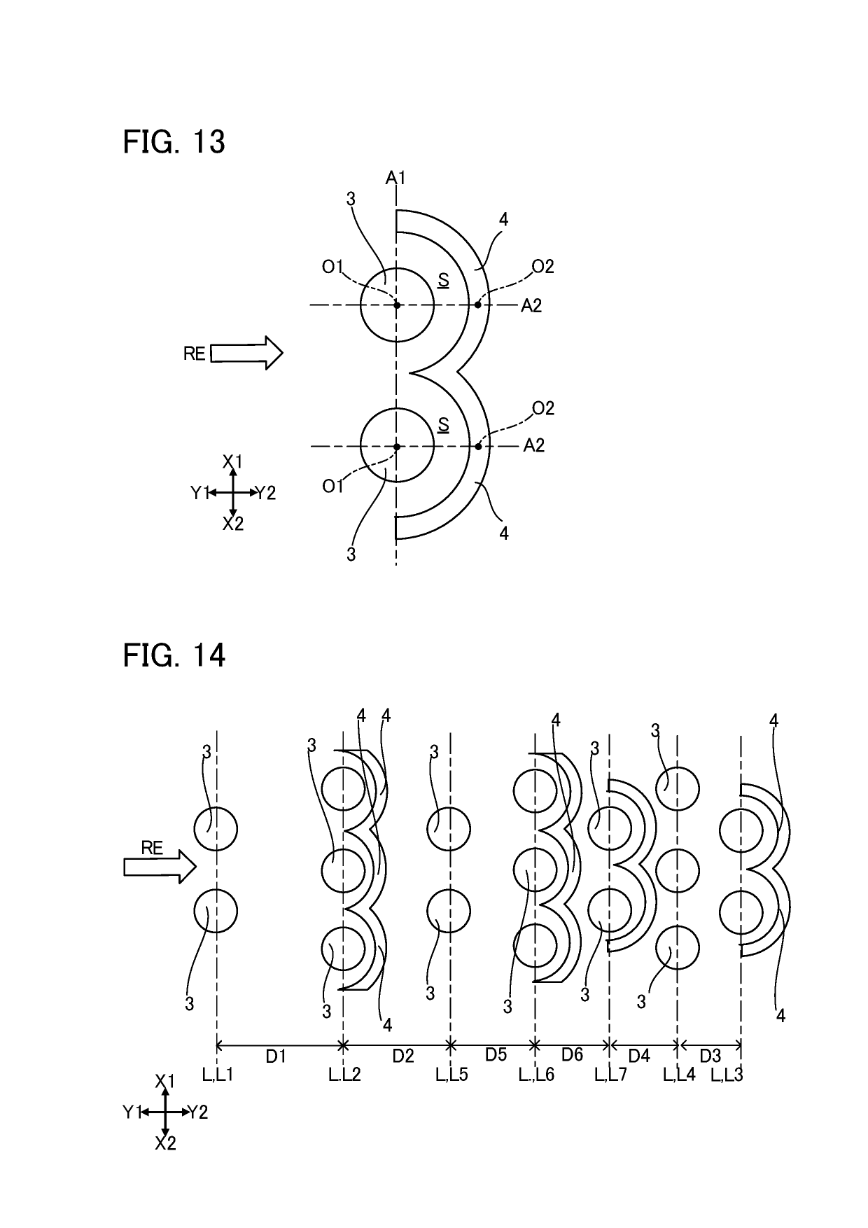

FIG. 13 illustrates protrusions 3 and baffles 4 shown in FIG. 7. As illustrated in FIG. 13, a situation will be considered in which a virtual line A1 passes through the center O1 of the protrusion 3 in plan view along the X1 direction, which is perpendicular to the direction of flow of the refrigerant RE. In this situation, each baffle 4 is positioned closer to the outlet 102H than the virtual line A1 of the corresponding protrusion 3.

Thus, the baffle 4 effectively serves to prevent a decrease in flow velocity and flow rate of the refrigerant RE in the downstream region of the baffle 4 (the region toward the outlet 102H). It is noted that the baffle 4 may include a portion positioned closer to the inlet 101H than the virtual line A1. However, in this configuration, the flow rate and flow velocity of the refrigerant RE may decrease in the region S, as compared to when the baffle 4 does not include such a portion.

Baffles 4, corresponding to protrusions 3 located within the same protrusion row L, are connected to each other. That is, protrusions 3 include two or more protrusions 3 arranged to be spaced apart from each other in the X1 direction, which is orthogonal to the direction of flow of the refrigerant RE. Two or more baffles 4 corresponding to the two or more protrusions 3 are provided and are connected to each other.

Connecting the baffles 4 to each other, located within the same protrusion row L, serves to prevent a decrease in the flow velocity and flow rate of refrigerant RE in the region S, as compared to when the baffles 4 are not connected.

Each protrusion 3 is circular in plan view. In addition, each baffle 4 has an arc shape that corresponds to the shape of the protrusion 3 in plan view. The arc-shaped baffles 4 increase the flow rate and flow velocity of the refrigerant RE in the region S without requiring an offset, as compared with straight baffles.

Each baffle 4 is concentric with the protrusion 3. Therefore, the distance between the baffle 4 and the protrusion 3 remains uniform across the entire region of the baffle 4. A line segment A2, extending through the center O1 of the protrusion 3 in the direction of flow of the refrigerant, also passes through the center O2 of the baffle 4. Each of the centers O1 and O2 is a geometric center in plan view.

Each baffle 4 concentric with the protrusion 3 increases the flow rate and flow velocity of the refrigerant RE in the region S, without requiring an offset.

In this embodiment, the baffles 4 are arranged for all of the protrusions 3. That is, these baffles 4 correspond one-to-one to the protrusions 3. This arrangement prevents a decrease in flow velocity and flow rate of the refrigerant RE in the downstream region of all the protrusions 3 (the region toward the outlet 102H), which effectively improves the cooling performance of the cooler 100.

### 2. Modifications

This disclosure is not limited to the foregoing embodiment, and a variety of modifications can be derived as described below. These modifications can be appropriately combined as long as they do not conflict.

### 2-1. First Modification

FIG. 14 is a plan view illustrating protrusions 3 and baffles 4 according to a first modification. As illustrated in FIG. 14, this modification does not need baffles 4 for all of the protrusions 3. In the example of FIG. 14, no baffles 4 are arranged for protrusions 3 located within the first protrusion row L1, the fourth protrusion row L4, and the third-closest protrusion row L to the inlet 101H. Baffles 4 are arranged for protrusions 3 located within the remaining protrusion rows L.

As described, this modification does not need baffles 4 for the respective protrusions 3. That is, baffles 4 are arranged for a subset of the protrusions 3. Stated differently, the baffles 4 are arranged for the respective protrusions 3.

At least one baffle 4 may be disposed on the third surface 103. In this case, the at least one baffle 4 may be disposed for the at least one protrusion 3 and enhances the cooling performance of the cooler 100.

### 2-2. Second Modification

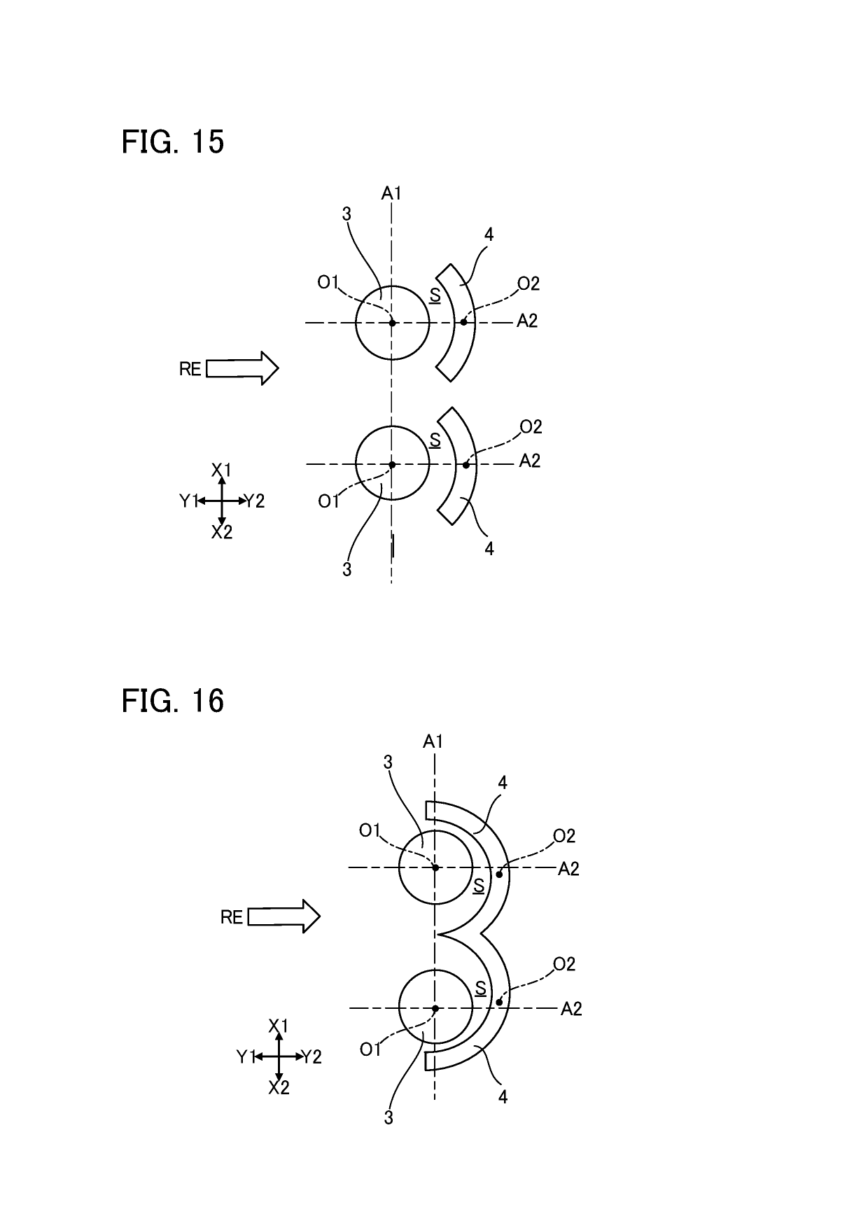

FIG. 15 is a plan view illustrating baffles 4 according to a second modification. In the second modification, as illustrated in FIG. 15, baffles 4 for a subset of the protrusions 3 located with the same protrusion row L are not connected to each other, but are instead spaced apart. That is, the protrusions 3 include two or more protrusions 3 that are arranged and spaced apart from each other along the X1 direction, which is orthogonal to the direction of flow of the refrigerant RE. Two or more baffles 4 are arranged for the respective two or more protrusions 3. The two or more baffles 4 are spaced apart from each other. Additionally, all of the baffles 4 are spaced apart from each other.

The arrangement of these baffles 4 at intervals within the same protrusion row L effectively prevents a reduction in the flow rate and flow velocity of the refrigerant RE within region S, as compared to when the baffles 4 are interconnected. Furthermore, the baffles 4 serve to prevent an increase in pressure loss, thereby maintaining a higher overall flow rate.

### 2-3. Third Modification

FIG. 16 is a plan view illustrating baffles 4 according to a third modification. In the third modification illustrated in FIG. 16, each baffle 4 is not concentric with a corresponding protrusion 3. A distance between the baffle 4 and the protrusion 3 varies over the entire region of the baffle 4. A line segment A2, which extends through the center O1 of the protrusion 3 in the direction of flow of refrigerant RE, does not intersect the center O2 of baffle 4.

Thus, each baffle 4 may be offset relative to the corresponding protrusion 3. For example, the placement of each baffle 4 may be offset relative to the protrusion 3 depending on the distance to the side wall 15. Similarly, the offset may be determined based on imbalances in the flow rate and flow velocity of refrigerant RE.

### 2-4. Fourth Modification

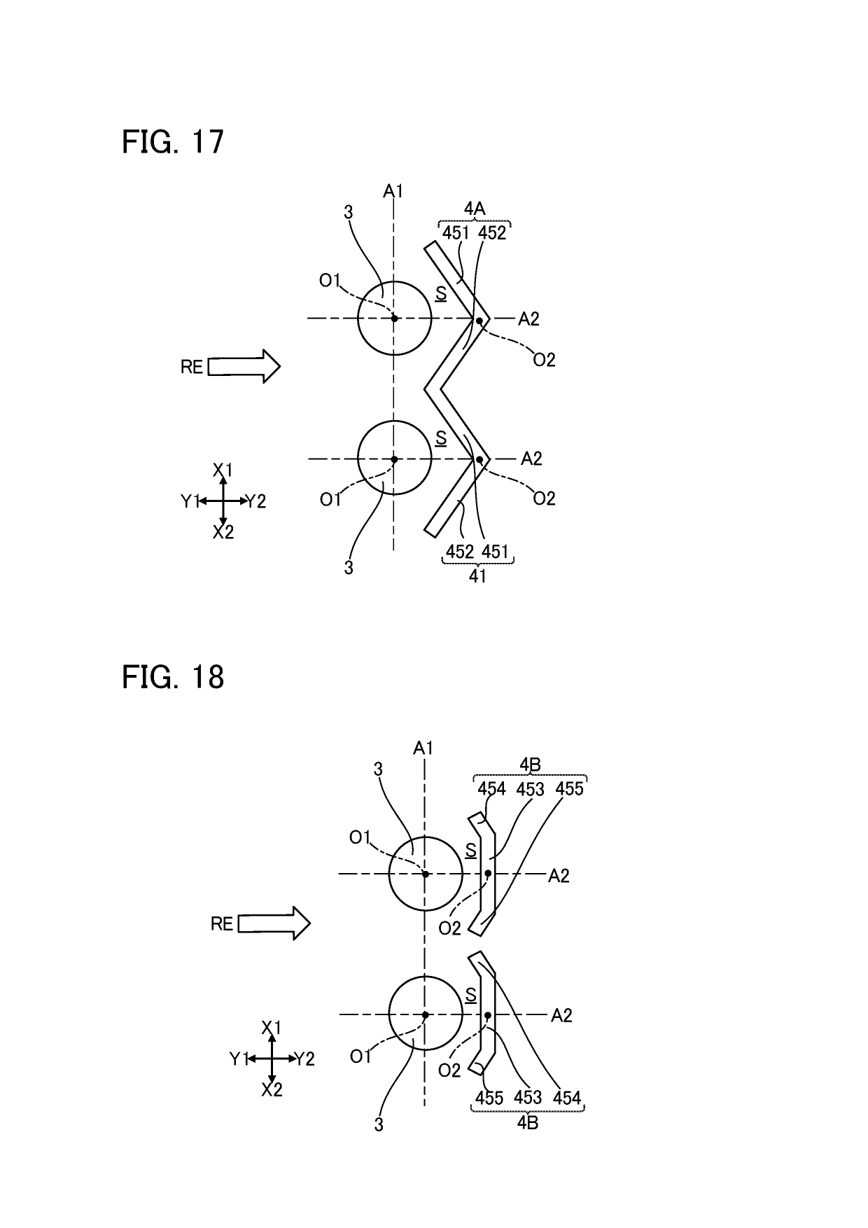

FIG. 17 is a view illustrating baffles 4A according to a fourth modification. Each baffle 4A, according to the fourth modification illustrated in FIG. 17, includes a straight portion rather than an arc-shaped portion in plan view. Specifically, each baffle 4A includes a first baffle 451 and a second baffle 452. The first baffle 451 extends linearly from the center O2 and is oriented toward the upper-left direction on the paper surface (a direction of intersection of the X and Y axes). The second baffle 452 also extends linearly from the center O2 but is oriented toward the lower-left direction (the direction of intersection of the X and Y axes). The portion of baffle 4A through which line segment A2 passes is located closest to outlet 102H. The baffles 4A for the respective protrusions 3 located within the same protrusion row L are connected to each other, although they may be spaced apart.

These baffles 4A serve to prevent decreases in flow rate and flow velocity in the region S.

### 2-5. Fifth Modification

FIG. 18 is a view illustrating baffles 4B according to a fifth modification. Each baffle 4B according to the fifth modification illustrated in FIG. 18 includes a straight portion rather than an arc-shaped portion in plan view. Specifically, each baffle 4B includes a third baffle 453, a fourth baffle 454, and a fifth baffle 455. The third baffle 453 passes through a line segment A2, and extends linearly in the X1 direction, which is orthogonal to the direction of flow of the refrigerant RE. The fourth baffle 454 extends linearly from a first end of the third baffle 453 and is oriented toward the upper-left direction on the paper surface (the direction of intersection of the X and Y axes). The fifth baffle 455 also extends linearly from a second end of the third baffle 453 but is oriented toward the lower-left direction (the direction of intersection of the X and Y axes). Baffles 4B, corresponding to protrusions 3 located within the same protrusion row L, are connected to each other, although they may be spaced apart.

These baffles 4B serve to prevent decreases in flow rate and flow velocity in the region S.

### 2-6. Sixth Modification

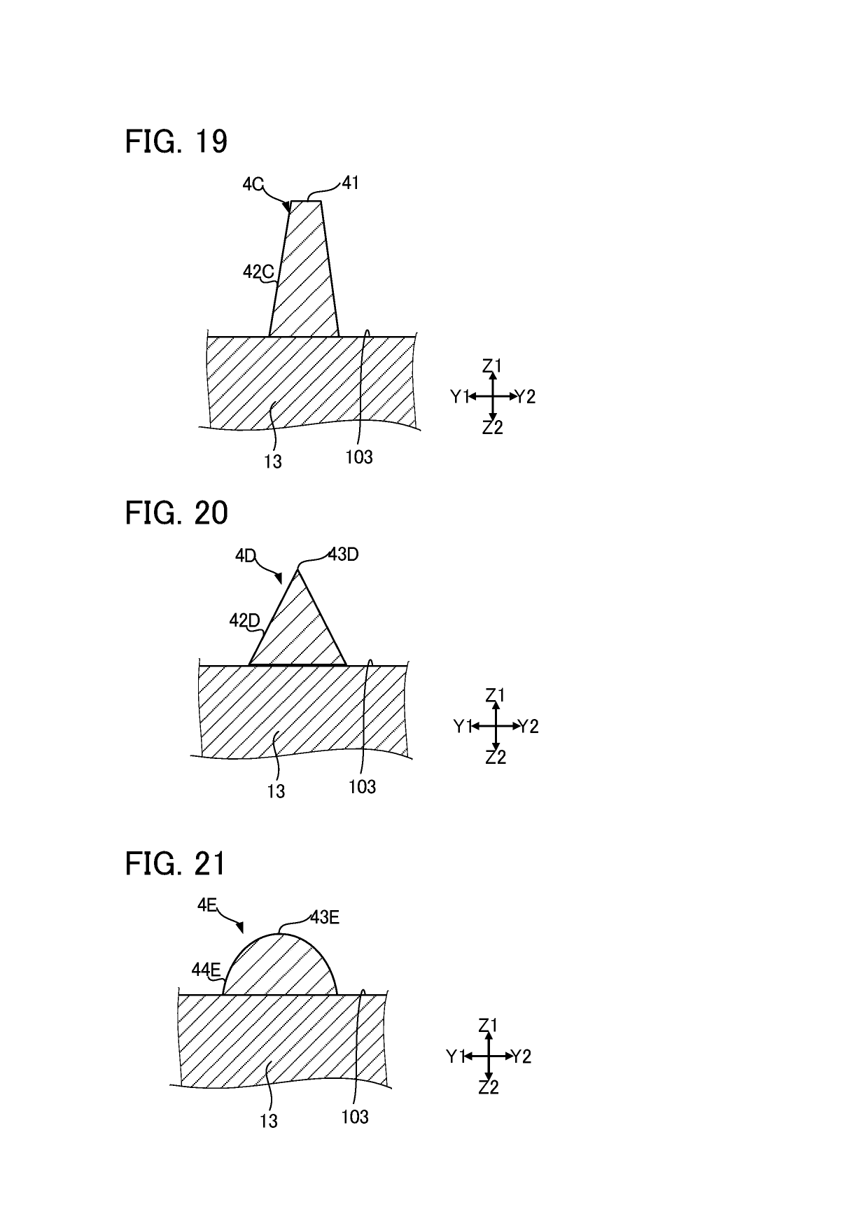

FIG. 19 is a view illustrating a baffle 4C according to a sixth modification. In the sixth modification illustrated in FIG. 19, a side surface 42C of the baffle 4C is non-parallel to the Z axis. The baffle 4C is trapezoidal in cross-section. The baffle 4C has a width that decreases with distance from the third surface 103.

### 2-7. Seventh Modification

FIG. 20 is a view illustrating a baffle 4D according to a seventh modification. In the seventh modification illustrated in FIG. 20, the baffle 4D has a vertex 43D and a side surface 42D. The side surface 42D is non-parallel to the Z axis. The baffle 4D is triangular in cross-section and has a width that decreases as it extends away from the third surface 103. The width tapers to zero at the vertex 43D.

### 2-8. Eighth Modification

FIG. 21 is a view illustrating a baffle 4E according to an eighth modification. In the eighth modification illustrated in FIG. 21, the baffle 4E has a vertex 43E and an outer surface 44E. The outer surface 44E is hemispherical. The baffle 4E is semicircular in cross-section.

### 2-10. Other Modifications

The shape of the baffle 4 is not limited to those described in the first embodiment and the sixth, seventh, and eighth modifications. For example, the inclination angle of the side surface 42 of the baffle 4 relative to the Z axis may differ between the upstream region of the baffle 4 (the region toward the inlet 101H) and the downstream region thereof (the region toward the outlet 102H). The top surface 41 may be non-parallel to the third surface 103. Not all of the baffles 4 necessarily have different shapes or protruding heights.

The shape of the protrusion 3 is not limited to that described in the first embodiment. For example, the protrusion 3 may have a shape similar to that of the baffle 4 described in the sixth, seventh, or eighth modifications. For example, the inclination angle of the side surface 42 of the protrusion 3 relative to the Z axis may differ between the upstream region of the protrusion 3 (the region toward the inlet 101H) and the downstream region thereof (the region toward the outlet 102H). The top surface 31 may be non-parallel to the third surface 103. Not all of the protrusions 3 necessarily have different shapes and protruding heights.

Although this disclosure has been described with reference to the illustrated embodiment, it is not limited thereto. Each element of this disclosure may be substituted with any configuration that performs a function similar to that described in the foregoing embodiment, and additional configurations may also be incorporated.

### Supplemental Notes

The following aspects can be derived from the foregoing embodiments or modifications.

A cooler according to Aspect 1 includes a case including: an inlet for a refrigerant; an outlet for the refrigerant; a first member with a first surface that absorbs heat from a cooled body and a second surface opposite to the first surface; a second member with a third surface facing the second surface; and a plurality of columnar protrusions that extends from the third surface toward the second surface. The plurality of protrusions is grouped into two or more protrusion rows that are arranged at intervals along a first direction of flow of the refrigerant. The two or more protrusion rows includes: a first protrusion row closest to the inlet; a second protrusion row next closest to the inlet after the first protrusion row; a third protrusion row closest to the outlet; and a fourth protrusion row next closest to the outlet after the third protrusion row. A distance between the first protrusion row and the second protrusion row is greater than a distance between the third protrusion row and the fourth protrusion row.

According to Aspect 1, the flow velocity of the refrigerant in vicinity of the outlet increases, reducing uneven cooling on the first surface of the second member.

In Aspect 2 according to Aspect 1, distances between adjacent protrusion rows among the two or more protrusion rows gradually decrease from the inlet to the outlet.

According to Aspect 2, the flow velocity of the refrigerant gradually decreases from the inlet toward the outlet, effectively reducing uneven cooling on the first surface of the second member.

In Aspect 3 according to Aspect 2, a center of each of the plurality of protrusions located within the first protrusion row in plan view does not overlap a center of each of the plurality of protrusions located within the second protrusion row in plan view, when viewed in the first direction of flow of the refrigerant. A center of each of the plurality of protrusions located within the third protrusion row in plan view does not overlap a center of each of the plurality of protrusions located within the fourth protrusion row in plan view, when viewed in the first direction.

According to Aspect 3, the refrigerant can easily flow over the entire internal space, effectively reducing uneven cooling on the first surface.

In Aspect 4 according to any one of Aspects 1 to 3, the cooler further includes at least one baffle that is disposed for at least one protrusion from among the plurality of protrusions and extends from the third surface toward the second surface. The at least one baffle has a protruding height that is less than a protruding height of the at least one protrusion. The at least one baffle is spaced apart from the at least one protrusion and is disposed on a side opposite the inlet relative to the at least one protrusion.

The baffle serves to prevent a deceleration of flow of the refrigerant in the downstream region of the protrusions (the region toward the outlet), which enhances the cooling performance of the cooler.

### DESCRIPTION OF REFERENCES SIGNS

1... second member, 2... first member, 3... protrusion, 4, 4A, 4B, 4C, 4D, 4E... baffle, 9... cooled body, 10... case, 11... bottom, 13... base, 15... side wall, 31... top surface, 32... side surface, 41... top surface, 42, 42C, 42D... side surface, 43D, 43E... vertex, 44E... outer surface, 100... cooler, 101H... inlet, 102H... outlet, 103... third surface, 151... first side wall, 152... second side wall, 153... third side wall, 154... fourth side wall, 201... first surface, 202... second surface, 451... first baffle, 452... second baffle, 453... third baffle, 454... fourth baffle, 455... fifth baffle, A1... virtual line, A2... line segment, D1, D2, D3, D4... distance, L... protrusion row, L1... first protrusion row, L2... second protrusion row, L3... third protrusion row, L4... fourth protrusion row, L5... fifth protrusion row, O1, O2... center, RE... refrigerant, S, S0, Sx, Sy... region, T1, T2... protruding height, W3, W40, W41... width.

What is claimed is:

1. A cooler comprising:
a case comprising:
an inlet for a refrigerant;
an outlet for the refrigerant;
a first member with a first surface that absorbs heat from a cooled body and a second surface opposite to the first surface;
a second member with a third surface facing the second surface; and
a plurality of columnar protrusions that extends from the third surface toward the second surface,
wherein the plurality of protrusions is grouped into two or more protrusion rows that are arranged at intervals along a first direction of flow of the refrigerant,
wherein the two or more protrusion rows comprise:
a first protrusion row closest to the inlet;
a second protrusion row next closest to the inlet after the first protrusion row;
a third protrusion row closest to the outlet; and
a fourth protrusion row next closest to the outlet after the third protrusion row,
wherein a distance between the first protrusion row and the second protrusion row is greater than a distance between the third protrusion row and the fourth protrusion row.

2. The cooler according to claim 1,
wherein distances between adjacent protrusion rows among the two or more protrusion rows gradually decrease from the inlet to the outlet.

3. The cooler according to claim 2,
wherein a center of each of the plurality of protrusions located within the first protrusion row in plan view does not overlap a center of each of the plurality of protrusions located within the second protrusion row in plan view, when viewed in the first direction of flow of the refrigerant, and
wherein a center of each of the plurality of protrusions located within the third protrusion row in plan view does not overlap a center of each of the plurality of protrusions located within the fourth protrusion row in plan view, when viewed in the first direction.

4. The cooler according to claim 1, further comprising: at least one baffle that is disposed for at least one protrusion from among the plurality of protrusions and extends from the third surface toward the second surface,
wherein the at least one baffle has a protruding height that is less than a protruding height of the at least one protrusion, and
wherein the at least one baffle is spaced apart from the at least one protrusion and is disposed on a side opposite the inlet relative to the at least one protrusion.
